(19) United States
(12) Patent Application Publication
(10) Pub. No.: US 2026/0304669 A1
(43) Pub. Date: Oct. 1, 2026

(54) CAGE ASSEMBLY FOR MODULAR QUANTUM DEVICE

(71) Applicant: Mesa Quantum Systems, Inc., Boulder, CO (US)

(72) Inventors: Antonio Jose Yervez Gonzalez, Longmont, CO (US); William Raasch, Longmont, CO (US); Olawale Lawal, Sachse, TX (US); Sristy Agrawal, Longmont, CO (US)

(21) Appl. No.: 19/578,064

(22) Filed: Mar. 25, 2026

Related U.S. Application Data
(60) Provisional application No. 63/778,547, filed on Mar. 27, 2025.

(51) Int. Cl. H05K 7/14; G02B 1/00; G02B 1/11; G04F 5/14; H05K 7/18

(52) U.S. Cl. CPC H05K 7/1424; G02B 1/002; G02B 1/11; G04F 5/14; H05K 7/1428; H05K 7/1455; H05K 7/1461; H05K 7/18

(57) ABSTRACT

An apparatus for assembling a modular quantum device may include a cage structure defining a plurality of spaced, substantially parallel slots and a plurality of blade modules. Each blade module may be insertable into a corresponding slot of the cage structure and carries one or more functional quantum device components. The cage structure constrains the blade modules to a predetermined positional alignment during an assembly process that electrically connects the blade modules to a circuit substrate.

### PRIORITY

This application claims the benefit of U.S. Provisional Patent Application No. 63/778,547, filed Mar 27, 2025, entitled CAGE-BASED ASSEMBLY SYSTEM FOR MODULAR QUANTUM DEVICES and naming Antonio Jose Yervez Gonzalez as the inventor, the disclosure of which is incorporated herein in its entirety by reference.

### FIELD

Illustrative embodiments of the invention generally relate to quantum sensing devices and methods for manufacturing quantum sensing devices. More particularly, various embodiments of the invention relate to modular architectures for hermetic quantum sensors including atomic clocks, magnetometers, and gyroscopes.

### BACKGROUND

Quantum sensors such as chip-scale atomic clocks (CSACs), atomic magnetometers, and quantum gyroscopes typically require multiple functional components operating along an optical interaction axis, including a light source, optical conditioning elements, an atomic vapor cell containing an alkali metal vapor, and a photodetector. These devices can be fabricated using different approaches for semiconductor-based implementations and glass fabrication methods for glass-type cells. Each component has different optimal operating temperatures, and traditional designs place all components in close physical proximity within a monolithic assembly, creating challenges for independent temperature control, component testing, and manufacturing yield.

### SUMMARY OF VARIOUS EMBODIMENTS

Illustrative embodiments enable the use of modular pre-tested and temperature-adjusted assemblies directly into vapor cell manufacturing processes, dramatically lowering production time and costs and improving thermal compatibility of quantum sensors, including quantum atomic clocks, gyroscopes, and magnetometers.

In accordance with one embodiment of the invention, an apparatus for assembling a modular quantum device may include a cage structure defining a plurality of spaced, substantially parallel slots and a plurality of blade modules. Each blade module may be insertable into a corresponding slot of the cage structure and carries one or more functional quantum device components. The cage structure constrains the blade modules to a predetermined positional alignment during an assembly process that electrically connects the blade modules to a circuit substrate.

In accordance with other embodiments, the assembly process may include reflow soldering.

In accordance with other embodiments, the assembly process may include a pressure fit or mechanical connector interface.

In accordance with other embodiments, the cage structure may be formed from a material having a low outgassing rate compatible with vacuum operation below 10⁻² Torr.

In accordance with other embodiments, the cage structure may be formed from a thermally insulating polymer having a thermal conductivity below 1 W/m-K, reducing conductive thermal transfer between adjacent blade modules.

In accordance with other embodiments, the thermally insulating polymer may include polyether ether ketone (PEEK), polyetherketoneketone (PEKK), or polyeherimide (PEI).

In accordance with other embodiments, each blade module may include a printed circuit board having a first portion carrying the functional quantum device component and a second portion carrying electrical connection pads.

In accordance with other embodiments, the printed circuit board may have a generally T-shaped profile.

In accordance with other embodiments, one or more of the cage structure and the blade modules may include keyed features configured to prevent incorrect insertion or orientation of a blade module.

In accordance with other embodiments, each blade module may include a non-volatile memory storing blade identification data and calibration data associated with that blade module.

In accordance with other embodiments, the calibration data may include one or more of thermistor characterization data over temperature, light source center frequency at operating temperature, or atomic vapor cell turnover temperature.

In accordance with other embodiments, the non-volatile memory is readable by the circuit substrate upon electrical connection to identify blade type and verify correct slot placement.

In accordance with other embodiments, the apparatus may further include one or more optical elements positioned between adjacent blade modules within the cage structure The one or more optical elements are thermally transmissive to visible and near-infrared wavelengths while attenuating thermal radiation transfer between adjacent blade modules.

In accordance with other embodiments, the one or more optical elements are slidably receivable into one or more slots of the cage structure.

In accordance with other embodiments, the one or more optical elements may include an anti-reflection coating configured for wavelengths between 780 and 900 nm.

In accordance with other embodiments, the one or more optical elements may include one or more metasurfaces configured to modify one or more properties of light transmitted therethrough, including one or more of a polarization state, a beam collimation amount, an optical density, a beam size, a beam profile, and a beam path.

In accordance with other embodiments, the one or more metasurfaces may be configured to provide quarter-wave retardation to circularly polarize light transmitted from a light source blade toward an atomic vapor cell blade.

In accordance with other embodiments, the cage structure provides mechanical support sufficient to maintain optical alignment of components on the blade modules during the assembly process.

In accordance with other embodiments, the cage structure may be configured to be compatible with automated pick-and-place assembly equipment.

In accordance with other embodiments, a quantum device system may include a plurality of modular blade assemblies, each blade assembly carrying a distinct quantum device function, a cage structure that receives and mechanically aligns the blade assemblies in a fixed spatial relationship, and a circuit substrate electrically connected to the blade assemblies while the blade assemblies are retained within the cage structure.

In accordance with other embodiments, the modular blade assemblies may include at least a light source blade, an atomic vapor cell blade, and a photodetector blade.

In accordance with other embodiments, the cage structure maintains alignment of the blade assemblies during reflow soldering.

In accordance with other embodiments, the cage structure may contribute structural rigidity sufficient to improve resistance to shock and vibration in the assembled quantum device.

In accordance with other embodiments, the assembly further includes one or more optical elements positioned between adjacent blade assemblies within the cage structure. The one or more optical elements may be transmissive to visible and near-infrared wavelengths while attenuating thermal radiation transfer between adjacent blade assemblies.

In accordance with other embodiments, the one or more optical elements are configured to be slidably receivable into one or more slots of the cage structure.

In accordance with other embodiments, the quantum device system may be configured as an atomic clock.

In accordance with other embodiments, a method of manufacturing a modular quantum device may include independently manufacturing and testing a plurality of blade modules, each blade module providing a distinct quantum device function, inserting the tested blade modules into corresponding slots of a cage structure to establish a predetermined alignment, positioning a circuit substrate relative to the blade modules, and electrically connecting the blade modules to the circuit substrate while the cage structure maintains the predetermined alignment.

In accordance with other embodiments, inserting the tested blade modules includes reading blade identification data from a non-volatile memory on each blade module to verify correct slot placement prior to electrically connecting the blade modules to the circuit substrate.

In accordance with other embodiments, the method further includes reworking the modular quantum device by thermally releasing the circuit substrate from one or more blade modules, removing at least one blade module from the cage structure, inserting a replacement blade module into the corresponding slot, and re-joining the circuit substrate to the blade modules.

In accordance with other embodiments, thermally releasing includes desoldering the circuit substrate.

In accordance with other embodiments, the method further includes independently testing the replacement blade module prior to insertion.

In accordance with other embodiments, independently testing the blade modules may include testing each blade module at its target operating temperature prior to integration with other blade modules.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows top and bottom isometric views of a cage structure in accordance with embodiments of the invention.

FIG. 2A schematically shows a side view of a blade module in accordance with embodiments of the invention.

FIG. 2B schematically shows a side view of a VCSEL blade module in accordance with embodiments of the invention.

FIG. 2C schematically shows a side view of a vapor cell blade module in accordance with embodiments of the invention.

FIG. 2D schematically shows a side view of a photodetector blade module in accordance with embodiments of the invention.

FIG. 2E schematically shows a side view of an optical element blade module in accordance with embodiments of the invention.

FIG. 3 schematically shows isometric and top views of a circuit substrate assembly in accordance with embodiments of the invention.

FIG. 4 schematically shows a blade insertion sequence to a cage structure in accordance with embodiments of the invention.

FIG. 5 schematically shows blade module loading and circuit substrate attachment to a cage structure in accordance with embodiments of the invention.

FIG. 6A schematically shows an optical element blade in accordance with embodiments of the invention.

FIG. 6B schematically shows optical blade installation details to a cage structure in accordance with embodiments of the invention.

FIG. 7 schematically shows details of blade thermal isolation in accordance with embodiments of the invention.

FIG. 8 shows a flowchart of manufacturing assembly process for a modular quantum sensor in accordance with embodiments of the invention.

### DESCRIPTION OF ILLUSTRATIVE EMBODIMENTS

Quantum sensors such as chip-scale atomic clocks (CSACs), atomic magnetometers, and quantum gyroscopes require multiple functional components operating along a common optical interaction axis. These components typically include a light source such as a vertical-cavity surface-emitting laser (VCSEL), one or more optical conditioning elements, an atomic vapor cell, and a photodetector. Each component must be precisely positioned and maintained in optical alignment to achieve target device performance.

Traditional quantum sensor designs achieve this alignment through monolithic assembly, in which all functional components are placed in close physical proximity within a single integrated structure. While this approach can achieve the required optical alignment, it creates significant manufacturing challenges that limit production yield and restrict scalability to higher production volumes.

A first challenge is the inability to independently test functional components prior to final assembly. In a monolithic assembly, individual component performance can only be verified after the complete device is assembled. A single defective component discovered at this stage requires scrapping or reworking the entire assembly, resulting in late-stage yield losses that become increasingly costly as quantum sensors incorporate more complex integrated optical and electronic components.

A second challenge relates to component characterization. Because monolithic assembly combines all functional components into a single structure at a fixed operating point, manufacturers must pre-select and match components whose characteristics are compatible before assembly — a process commonly referred to as component binning. For example, in a CPT-based atomic clock using rubidium, the VCSEL must emit at approximately 795 nm at its operating temperature. In a monolithic assembly, the VCSEL operating temperature is constrained by the assembly as a whole, requiring manufacturers to sort and match VCSELs by wavelength characteristics before assembly. Similarly, the turnover temperature of the atomic vapor cell and the linearity characteristics of associated thermistors must be matched to compatible ranges before integration. This binning requirement increases component inventory, reduces manufacturing flexibility, and limits the ability to optimize individual component performance after assembly.

A modular assembly approach offers a path to capturing individual component characterization data — including VCSEL operating wavelength at temperature, vapor cell turnover temperature, and thermistor linearity correction data — during pre-assembly burn-in and independent testing. However, existing modular assembly approaches for quantum sensors have not provided a practical means of preserving and communicating this characterization data through the assembly process to the completed device, where it could be used to fine-tune system operation based on the known characteristics of each individual component.

A third challenge is assembly scalability. Monolithic quantum sensor assembly relies heavily on manual processes that introduce variability and limit production volume. The precise placement and alignment of optical components along the interaction axis requires skilled technicians and is difficult to replicate consistently at high volumes. These factors combine to create production bottlenecks that increase unit costs and limit the availability of quantum sensors for broader commercial applications.

A fourth challenge is reworkability. In a monolithic assembly, there is no practical path to replacing a single underperforming or failed component without disassembling and potentially scrapping the entire device. This limitation increases the cost of quality failures discovered after assembly and eliminates the possibility of field replacement or performance optimization of individual functional modules.

What is needed is a quantum sensor assembly system that enables independent manufacturing, characterization, and testing of functional modules prior to final assembly, preserves individual component characterization data through the assembly process for use in system-level performance optimization, maintains precise optical alignment of functional components during automated assembly and reflow soldering, supports standard surface-mount technology manufacturing processes compatible with high-volume production, and provides a practical path to rework or replacement of individual functional modules without scrapping the complete assembly.

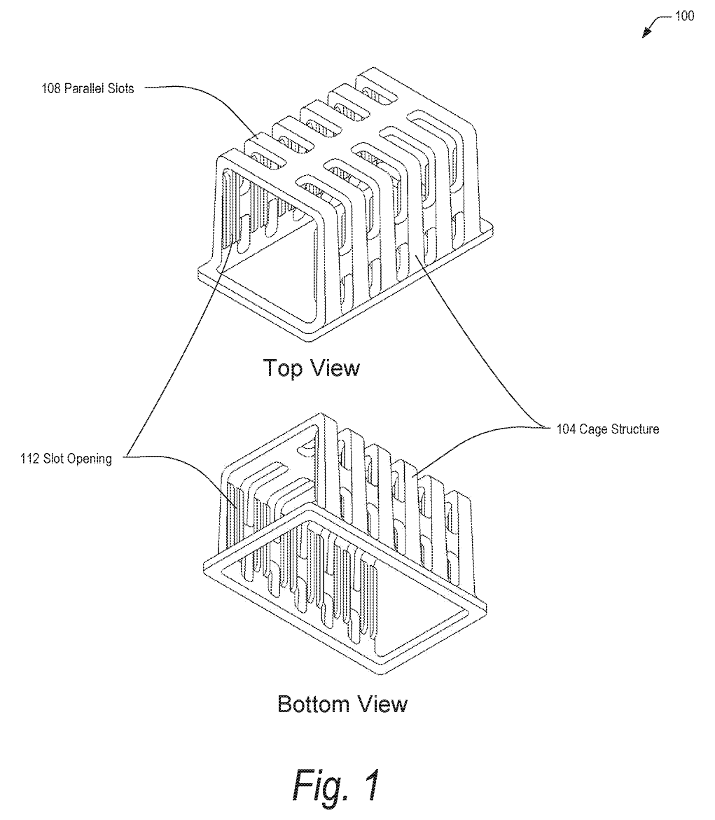

Referring to FIG. 1, top and bottom isometric views of a cage structure 104 in accordance with embodiments of the invention are shown. The cage structure 104 includes a plurality of spaced substantially parallel slots 108 extending through the structure and defined by a surrounding frame. Each slot 108 includes a slot opening 112 configured to receive a blade module. The cage structure 104 is configured to mechanically constrain inserted blade modules in a predetermined spatial relationship, thereby maintaining alignment during assembly and subsequent processing. In some embodiments, the cage structure 104 is formed from a high-temperature, low-outgassing material compatible with reflow soldering and vacuum environments, and includes structural support elements that maintain dimensional stability and alignment of the slots 108 during thermal cycling. The arrangement of the parallel slots 108 enables precise positioning of multiple blade modules along a common axis while allowing insertion and retention through the slot openings 112.

In some embodiments, the cage structure 104 is formed from a thermally insulating polymer material having a thermal conductivity less than approximately 1 W/m-K, including but not limited to polyether ether ketone (PEEK), polyetherketoneketone (PEKK), or polyetherimide (PEI), thereby reducing conductive thermal transfer between blade modules positioned in adjacent slots 108. The cage structure 104 may further be formed from a material having a low outgassing rate compatible with vacuum operation below approximately 10⁻² Torr.

The parallel slots 108 may include keyed features, such as asymmetrical geometries or varying widths, configured to prevent incorrect insertion or orientation of blade modules. The cage structure 104 further provides sufficient mechanical rigidity to maintain optical alignment of components disposed on the blade modules during assembly processes, including reflow soldering, and may be configured for compatibility with automated pick-and-place equipment.

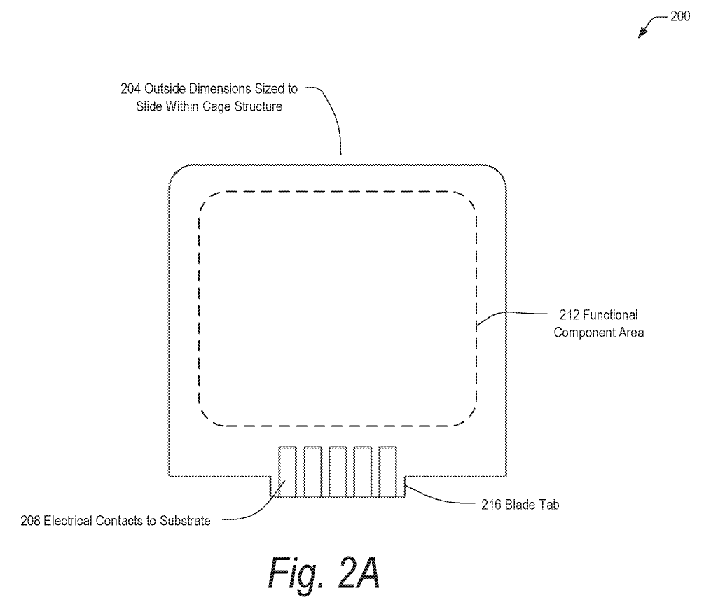

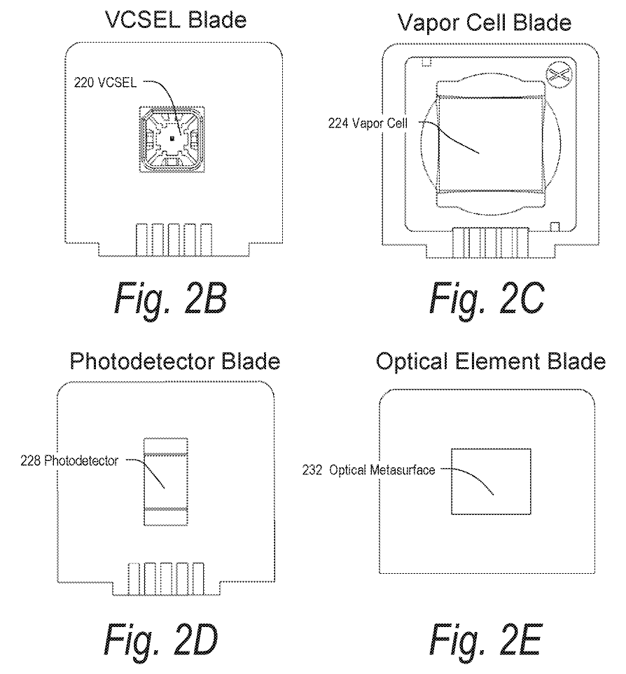

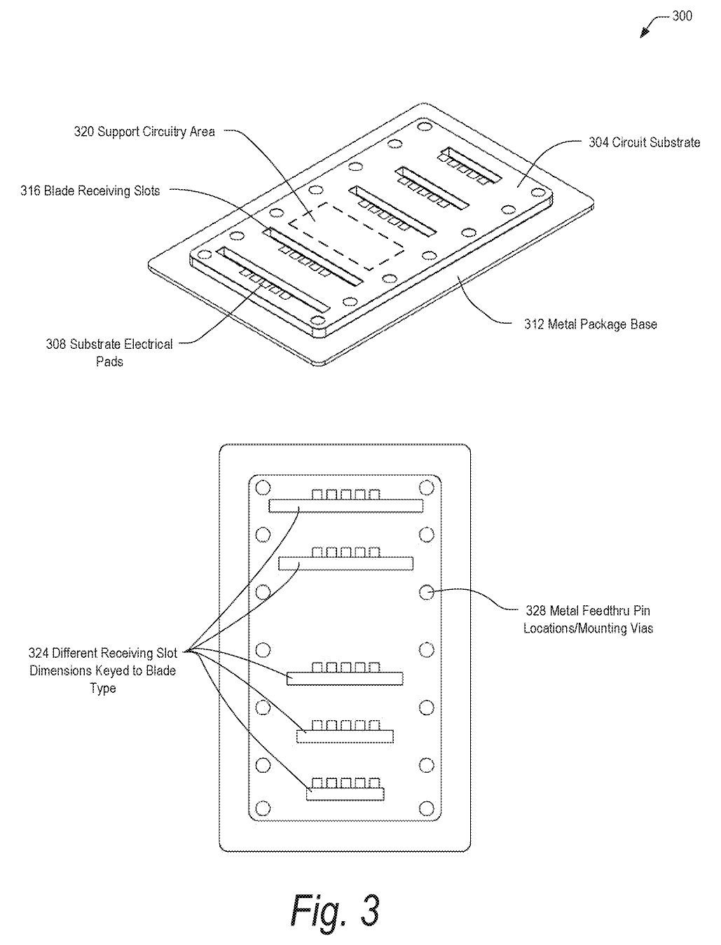

Referring to FIG. 2A, a side view of a blade module 200 in accordance with embodiments of the invention is shown. The blade module 200 includes outside dimensions 204 sized to slide within the slots of the cage structure, electrical contacts 208 configured to electrically couple the blade module 200 to a circuit substrate, a functional component area 212, and a blade tab 216. The blade module 200 may comprise a generally T-shaped printed circuit board (FR-4 or equivalent construction), with the functional component area 212 disposed on an upper portion and the electrical contacts 208 disposed on a lower stem portion, thereby enabling insertion into the cage structure while providing electrical connection at the blade tab 216.

In some embodiments, blade modules 200 may further include a non-volatile memory device disposed within the functional component area 212 or electrically coupled to the electrical contacts 208. The non-volatile memory may store blade identification data and calibration data associated with the blade module 200, including thermistor characterization data, light source wavelength data, or vapor cell operating parameters. The non-volatile memory may be readable by the circuit substrate 304 upon electrical connection to verify blade type and proper slot placement.

Referring to FIGS. 2B–2E, various exemplary blade modules for a quantum sensor are illustrated. Each of the blade modules has a different function and construction. Each blade module is independently manufacturable and testable prior to assembly and may include keyed physical features and alignment structures configured to interface with corresponding features of the cage structure 104 to ensure correct orientation and placement. In some embodiments, the blade modules may be configured to carry distinct functional components of a quantum device, including light sources, atomic reference elements, optical conditioning elements, and detectors.

The plurality of blade modules 200 collectively define modular blade assemblies, each carrying a distinct quantum device function and arranged along an optical interaction axis when inserted into the cage structure 104. In some embodiments, the blade modules 200 may include at least a light source blade (FIG. 2B), an atomic vapor cell blade (FIG. 2C), and a photodetector blade (FIG. 2D), with one or more optical element blades (FIG. 2E) positioned between adjacent blade modules 200.

FIG. 2B illustrates a side view of a VCSEL blade module in accordance with embodiments of the invention is shown. The VCSEL blade module includes a VCSEL 220 disposed within the functional component area 212. FIG. 2C illustrates a side view of a vapor cell blade module in accordance with embodiments of the invention. The vapor cell blade module includes a vapor cell 224. FIG. 2D illustrates a side view of a photodetector blade module in accordance with embodiments of the invention. The photodetector blade module includes a photodetector 228. FIG. 2E illustrates a side view of an optical element blade module in accordance with embodiments of the invention. The optical element blade module includes an optical metasurface 232.

The optical element blade including optical metasurface 232 may be configured to be transmissive to visible and near-infrared wavelengths while attenuating thermal radiation transfer between adjacent blade modules. In some embodiments, the optical metasurface 232 includes an anti-reflection coating configured for wavelengths between approximately 780 nm and 900 nm.

The optical metasurface 232 may further be configured to modify one or more properties of transmitted light, including polarization state, beam collimation, optical density, beam size, beam profile, or beam path. In one embodiment, the optical metasurface 232 provides quarter-wave retardation to convert linearly polarized light from a VCSEL blade 220 into circularly polarized light for interaction with a vapor cell 224.

Referring to FIG. 3, isometric and top views 300 of a circuit substrate assembly in accordance with embodiments of the invention are shown. The circuit substrate assembly 300 includes a circuit substrate 304 having a plurality of substrate electrical pads 308 arranged to correspond with electrical contacts of inserted blade modules. The circuit substrate 304 is supported by a metal package base 312 and includes a plurality of blade receiving slots 316 aligned with the slots of the cage structure 104. In some embodiments, the blade receiving slots 316 include different slot dimensions 324 keyed to corresponding blade module types to prevent incorrect insertion. The circuit substrate assembly 300 further includes a support circuitry area 320 for providing electrical power, signal processing, and control functions for the blade modules. Additionally, metal feedthrough pin locations or mounting vias 328 may be provided to enable electrical connection to external components and mechanical mounting. The circuit substrate 304 is configured to be positioned relative to the cage structure 104 such that, upon assembly, electrical contacts of the blade modules are aligned with the substrate electrical pads 308 for simultaneous connection, for example via reflow soldering.

When completely packaged as a quantum sensor, the metal package base 312 is attached to a package lid (not shown) to form a magnetic shield. The attachment means may include soldering, seam sealing, or laser welding, for example. The magnetic shield prevents stray external magnetic fields from influencing the magnetic coils associated with the vapor cell 224. The vapor cell 224 is an alkali metal vapor cell as understood by one of ordinary skill in the art. In one embodiment, the interior of the magnetic shield may be a partial or complete vacuum or filled with an inert gas such as argon or nitrogen. The metal package base 312 and package lid may be formed from mu-metal or other metallic compounds having strong resistive properties to external magnetic fields.

In some embodiments, the circuit substrate 304 is configured to electrically interface with non-volatile memory devices disposed on the blade modules 200 via the electrical contacts 208 and substrate electrical pads 308, thereby enabling identification of blade module type and verification of proper slot placement prior to electrical connection.

The circuit substrate 304 and substrate electrical pads 308 are further configured to permit simultaneous electrical connection of a plurality of blade modules 200 during a single assembly process, including reflow soldering. In alternative embodiments, the circuit substrate 304 may include mechanical or pressure-fit connector interfaces for engaging the electrical contacts 208 of the blade modules 200.

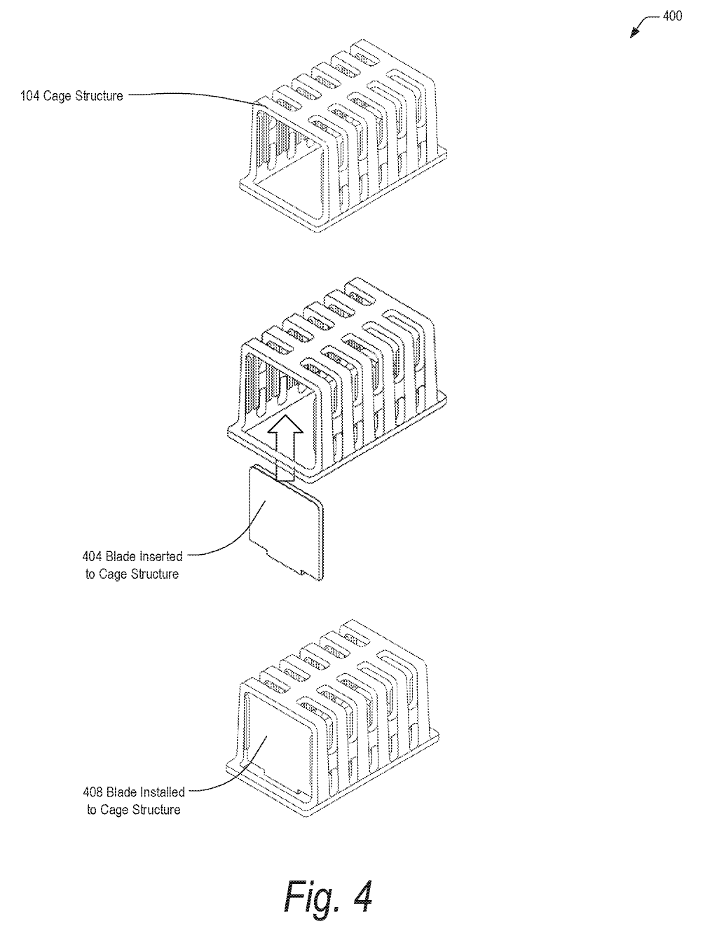

Referring to FIG. 4, a blade insertion sequence to a cage structure 400 in accordance with embodiments of the invention is shown. A blade module is inserted into the cage structure 104, as indicated at 404, by translating the blade module through the slot opening 112 and into a corresponding slot 108. The cage structure 104 guides the blade module during insertion and constrains its orientation using keyed features. Once fully inserted, the blade module is retained within the cage structure 104 in an installed position 408. The cage structure 104 maintains positional alignment of the blade module relative to other inserted blade modules and relative to the circuit substrate 304 during subsequent assembly operations. This guided insertion and retention enables consistent placement and reduces variability associated with manual assembly while supporting automated insertion processes.

In some embodiments, insertion of the blade module 200 into the cage structure 104 includes verifying blade identity and slot compatibility prior to full insertion, for example by reading blade identification data from a non-volatile memory associated with the blade module. The keyed features of the slots 108 and blade modules 200 cooperate to ensure correct placement.

The insertion process may be performed manually or via automated pick-and-place equipment configured to position and insert blade modules 200 into the cage structure 104 with controlled alignment and orientation.

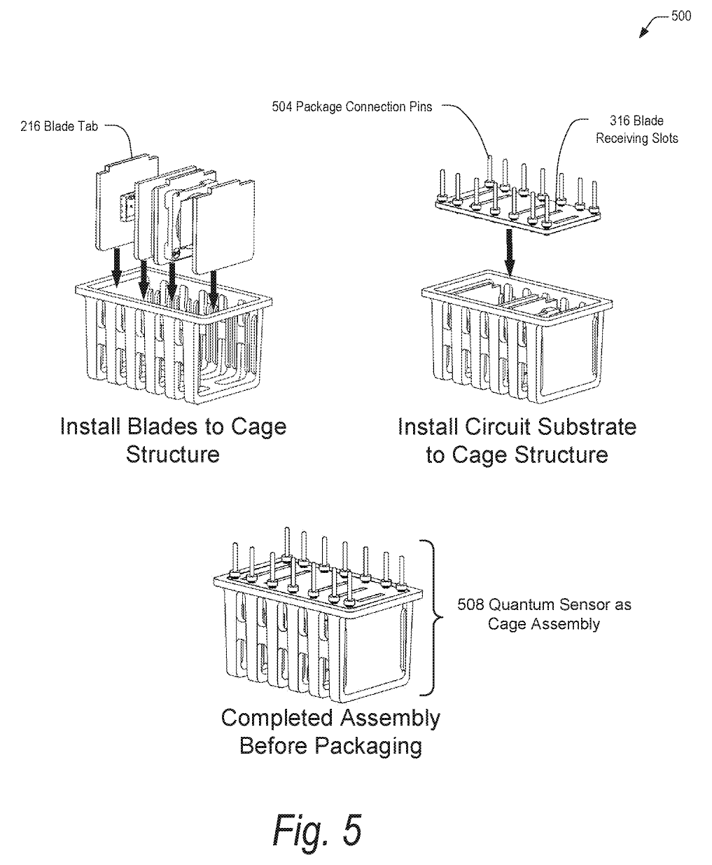

Referring to FIG. 5, blade module loading and circuit substrate attachment to a cage structure 500 in accordance with embodiments of the invention are shown.

A plurality of blade modules 200 are first installed into the cage structure 104 via their respective blade tabs 216, aligning the blade modules 200 within blade receiving slots 316. A circuit substrate 304 is then positioned relative to the cage structure 104 and blade modules 200 and includes package connection pins 504 for external electrical interfacing. The circuit substrate 304 is coupled to the blade modules 200 such that electrical contacts of the blade modules 208 engage corresponding pads on the circuit substrate 308. The resulting structure forms a quantum sensor cage assembly 508 prior to packaging. In some embodiments, the assembly process includes reflow soldering to simultaneously establish electrical connections between all blade modules 200 and the circuit substrate 304 while the cage structure 104 maintains alignment. This approach eliminates the need for discrete connectors and enables scalable, high-throughput manufacturing with improved structural integrity and alignment retention.

In some embodiments, the cage structure 104 maintains positional alignment of the blade modules 200 during reflow soldering of the electrical contacts 208 to the substrate electrical pads 308 of the circuit substrate 304. The cage structure 104 thereby enables simultaneous electrical connection of the plurality of blade modules 200 while preserving optical alignment.

The resulting cage assembly 508 provides enhanced structural rigidity relative to assemblies utilizing discrete connectors, thereby improving resistance to shock and vibration in the completed quantum device system.

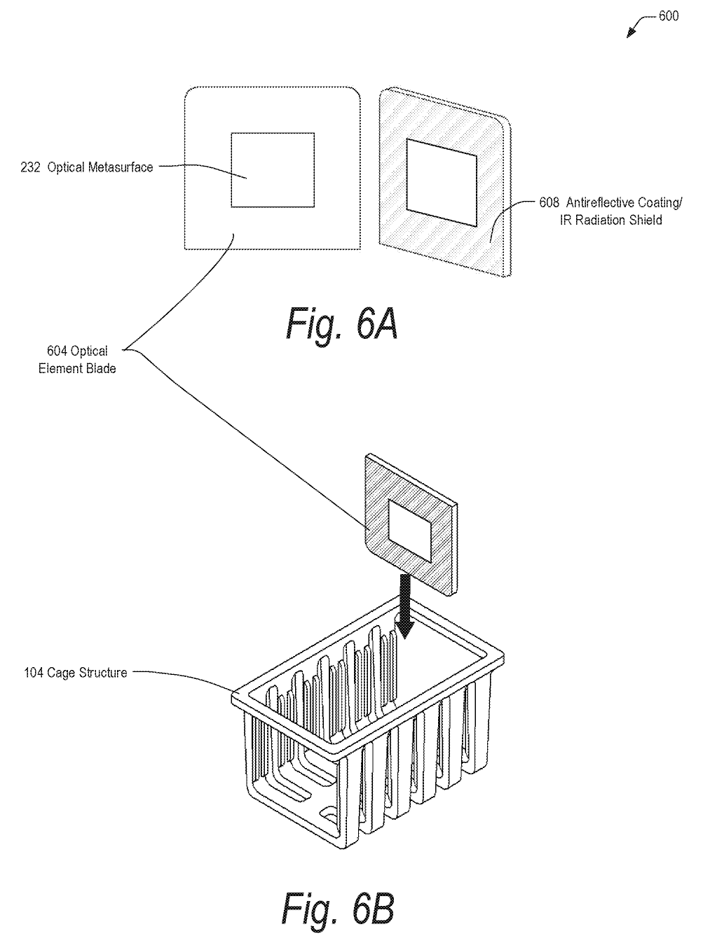

Referring to FIG. 6A, an optical element blade 600 in accordance with embodiments of the invention is shown. The optical element blade 600 is configured to transmit operational optical wavelengths while reducing thermal radiation transfer between adjacent blade modules 200. In some embodiments, the optical element blades 600 include coatings or metasurface structures 232 configured to modify optical properties including polarization, beam collimation, beam profile, or optical density. In one embodiment, optical element blades 600 may include an antireflective coating or infrared (IR) radiation shield 608 to limit or block thermal radiation.

Referring to FIG. 6B, optical blade installation details to a cage structure in accordance with embodiments of the invention are shown. One or more optical element blades 600, including optical metasurfaces 232, are inserted into corresponding slots 108 of the cage structure 104 between adjacent blade modules 200. The optical element blades 600 are slidably receivable into the slots 108 and are positioned to lie along the optical interaction axis defined by the blade modules 200.

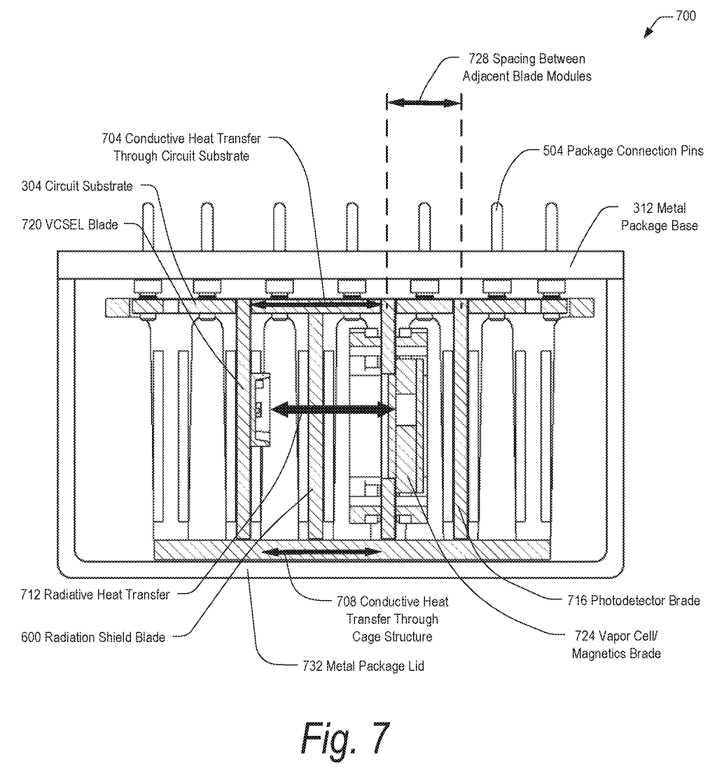

Referring to FIG. 7, details of blade thermal isolation 700 in accordance with embodiments of the invention are shown. FIG. 7 illustrates a cutaway of an upside down side view of a quantum sensor, with the package connecting pins 504 extending in an upward direction through the metal package base 312. A metal package lid 732 is attached to the metal package base 312 to form a hermetic quantum sensor. The hermetic seal allows the interior space of the quantum sensor to be pressurized or depressurized to a different pressure than atmospheric pressure and/or filled with an inert gas such as argon or nitrogen.

The optics/radiation shield blade 600 is positioned between the VCSEL blade 720 and the vapor cell/magnetics blade 724 and the vapor cell/magnetics blade 724 is positioned between the optics/radiation shield blade 600 and the photodetector blade 716. The optics/radiation shield blade 600 provides dual functionality critical to the thermal island architecture:
(1) Optical transparency along the interaction axis. The optics/radiation shield blade 600 is optically transparent at operational wavelengths corresponding to alkali metal atomic transitions. For rubidium-based vapor cells 224, the operational wavelength is approximately 795 nm (Rb D1 line). For cesium-based vapor cells 224, the operational wavelength is approximately 895 nm (Cs D1 line). The blade 600 permits transmission of light between active functional modules without substantial attenuation, beam distortion, or polarization degradation.
(2) Thermal radiation shielding. The optics/radiation shield blade 600 includes at least one thermally reflective surface oriented toward one or both adjacent active blades (e.g., the VCSEL blade 720 and/or the vapor cell/magnetics blade 724). The reflective surface 608 reduces radiative heat transfer 712 by reflecting infrared radiation while transmitting operational optical wavelengths. In certain embodiments, multilayer dielectric coatings may selectively reflect wavelengths above 2 micrometers (thermal infrared) while transmitting near-infrared wavelengths in the 750-900 nm range used for quantum sensing.

The optics/radiation shield blade 600 may further include low thermal conductivity materials to reduce conduction heat transfer, reduce cross-sectional mounting interfaces to minimize conduction paths, and operate within vacuum gaps or reduced-pressure environments adjacent to the blade. Thermal isolation is characterized such that adjustment of a first operating temperature (e.g., VCSEL blade 720 operating at 70-85°C) produces less than a predetermined change in the second operating temperature (e.g., vapor cell/magnetics blade 724 operating at 85-95°C). In some embodiments, the predetermined threshold is less than 5°C. These structural features distinguish the optics/radiation shield blade 600 from simple mechanical spacers and provide functional radiative decoupling while preserving optical alignment in a miniaturized quantum sensor device.

In certain embodiments, the optics/radiation shield blade 600 may include multilayer dielectric anti-reflection coatings 608 on optical surfaces to minimize reflection losses at the operational wavelengths (e.g., 795 nm for rubidium or 895 nm for cesium). The optics/radiation shield blade 600 may also incorporate additional optical conditioning elements such as metasurface features 232 for beam shaping, beam collimation, or quarter-wave plate functionality for polarization control.

In some embodiments, the cage structure 104 and spacing between adjacent blade modules 728 – which establishes a vacuum or low convectivity gas gap between adjacent blade modules 728 - cooperate with the optical element blade 600 to reduce conductive, convective, and radiative thermal transfer 712 between blade modules 200. The use of thermally insulating materials in the cage structure 104 and optical element blade 600 further enhances thermal isolation between modules operating at different temperatures. Conductive heat transfer through the cage structure 708 and the circuit substrate 704 is limited by the thermally resistive materials. Convective heat transfer between adjacent blade modules 728 is mitigated by the hermetic package environment established by the metal package base 312 and metal package lid 732 — either by evacuation to reduce internal pressure below approximately 10⁻² Torr, substantially eliminating convective transfer, or by backfilling with a low-convectivity inert gas such as argon or nitrogen.

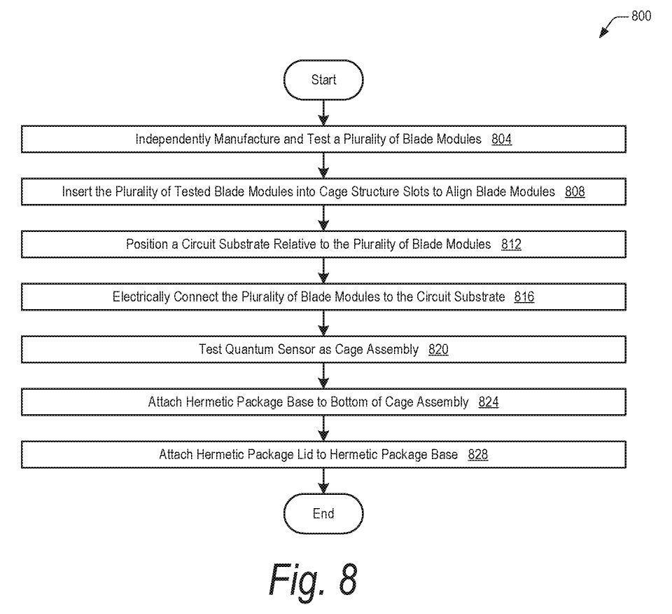

Referring to FIG. 8, a flowchart of a manufacturing assembly process for a modular quantum sensor 800 in accordance with embodiments of the invention is shown.

At block 804, the process includes independently manufacturing and testing a plurality of different blade modules 200. The independent testing may include one or more forms of parametric and functional characterization to ensure each blade module 200 functionally operates properly within established parameters. Flow proceeds to block 808.

At block 808, the process includes inserting the plurality of tested blade modules 200 into slots of a cage structure 104 to align the blade modules 200. In some embodiments, inserting the blade modules 200 into the cage structure 104 is performed using automated pick-and-place equipment. Flow proceeds to block 812.

At block 812, the process includes positioning a circuit substrate 304 relative to the plurality of blade modules 200. The positioning aligns the blade tab 216 of each blade module 200 with the corresponding blade receiving slot 316 of the circuit substrate 304 and the electrical contacts 208 of each blade module 200 to the corresponding substrate electrical pads 308 of the circuit substrate 104.

In some embodiments, the process further includes reading blade identification data from a non-volatile memory associated with each blade module 200 to verify correct slot placement. Flow proceeds to block 816.

At block 816, the process includes electrically connecting the plurality of blade modules 200 to the circuit substrate 304. In one embodiment, the electrical contacts 208 of each blade module 200 may be soldered to the corresponding substrate electrical pads 308 of the circuit substrate 104. In another embodiment, the circuit substrate 104 may have a mating electrical connector to receive the electrical contacts 208 of each blade module 200. Flow proceeds to block 820.

At block 820, the quantum sensor may be tested as an assembled cage assembly 508, prior to final packaging. This may beneficially allow for easier and faster rework to replace a blade module 200 or the circuit substrate 304 because the package lid and package base 312 do not need to be unsoldered and disassembled.

In some embodiments, the testing may reveal one or more failures that requires reworking the modular quantum device 508 by thermally releasing the circuit substrate 304 from one or more blade modules 200, removing at least one blade module 200 from the cage structure 104, inserting a replacement blade module 200 into a corresponding slot 108, and rejoining the circuit substrate 304 to the blade modules 200.

In some embodiments, thermally releasing the circuit substrate 304 may include desoldering electrical connections between the electrical contacts 208 and substrate electrical pads 308. In some embodiments, replacement blade modules 200 are independently tested prior to insertion, including testing at target operating temperatures. Flow proceeds to block 824.

At block 824, the metal package base 312 is attached to the bottom of the cage assembly 300. Sealing glass or other insulating hermetic compounds (an airtight epoxy, for example) may surround each of the package connection pins 504 and be applied to the gap around each pin 504. Flow proceeds to block 828.

At block 828, a hermetic package base may be attached to the metal package base 312 by various attachment operations known in the art. In one embodiment, the interior of the packaged quantum sensor is evacuated during the lid seal operation. In another embodiment, an inert gas such as nitrogen or argon may fill the packaged quantum sensor to absorb moisture. Flow ends at block 828.

The cage assembly architecture described herein is applicable across a broad range of quantum sensing devices, including but not limited to chip-scale atomic clocks, atomic magnetometers, and quantum gyroscopes. In each application, the modular architecture enables independent manufacturing, testing, and characterization of individual blade modules 200 prior to final assembly, with component calibration data preserved through the assembly process for use in system-level performance optimization. The cage structure 104 maintains precise optical alignment of blade modules 200 during assembly and electrical connection, supports compatibility with automated pick-and-place manufacturing processes, and provides a practical path to rework or replacement of individual blade modules 200 without scrapping the complete assembly. The alignment and assembly advantages described herein apply regardless of the electrical connection method employed, including reflow soldering, pressure fit, or mechanical connector interface. The same core blade types — light source, optical conditioning, vapor cell, and detection — may be adapted for different alkali metal species, optical wavelengths, and sensing modalities while retaining the manufacturing and assembly advantages described herein.

Various embodiments of the invention have been described in fulfillment of the various objectives of the invention. It should be recognized that these embodiments are merely illustrative of the principles of the present invention. Numerous modifications and adaptations thereof will be readily apparent to those skilled in the art without departing from the spirit and scope of the present invention as defined in the following claims.

What is claimed is:

1. An apparatus for assembling a modular quantum device, comprising:
a cage structure defining a plurality of spaced, substantially parallel slots;
a plurality of blade modules, each blade module being insertable into a corresponding slot of the cage structure and carrying one or more functional quantum device components,
wherein the cage structure constrains the blade modules to a predetermined positional alignment during an assembly process that electrically connects the blade modules to a circuit substrate.

2. The apparatus of claim 1, wherein the assembly process comprises reflow soldering.

3. The apparatus of claim 1, wherein the assembly process comprises a pressure fit or mechanical connector interface.

4. The apparatus of claim 1, wherein the cage structure is formed from a material having a low outgassing rate compatible with vacuum operation below 10⁻² Torr.

5. The apparatus of claim 1, wherein the cage structure is formed from a thermally insulating polymer having a thermal conductivity below 1 W/m-K, reducing conductive thermal transfer between adjacent blade modules.

6. The apparatus of claim 5, wherein the thermally insulating polymer comprises polyether ether ketone (PEEK), polyetherketoneketone (PEKK), or polyeherimide (PEI).

7. The apparatus of claim 1, wherein each blade module comprises a printed circuit board having a first portion carrying the functional quantum device component and a second portion carrying electrical connection pads.

8. The apparatus of claim 7, wherein the printed circuit board has a generally T-shaped profile.

9. The apparatus of claim 1, wherein one or more of the cage structure and blade modules includes keyed features configured to prevent incorrect insertion or orientation of a blade module.

10. The apparatus of claim 1, wherein each blade module comprises a non-volatile memory storing blade identification data and calibration data associated with that blade module.

11. The apparatus of claim 10, wherein the calibration data comprises one or more of thermistor characterization data over temperature, light source center frequency at operating temperature, or atomic vapor cell turnover temperature.

12. The apparatus of claim 10, wherein the non-volatile memory is readable by the circuit substrate upon electrical connection to identify blade type and verify correct slot placement.

13. The apparatus of claim 1, further comprising one or more optical elements positioned between adjacent blade modules within the cage structure, wherein the one or more optical elements are thermally transmissive to visible and near-infrared wavelengths while attenuating thermal radiation transfer between adjacent blade modules.

14. The apparatus of claim 13, wherein the one or more optical elements are slidably receivable into one or more slots of the cage structure.

15. The apparatus of claim 13, wherein the one or more optical elements comprises an anti-reflection coating configured for wavelengths between 780 and 900 nm.

16. The apparatus of claim 13, wherein the one or more optical elements comprises one or more metasurfaces configured to modify one or more properties of light transmitted therethrough, including one or more of a polarization state, a beam collimation amount, an optical density, a beam size, a beam profile, and a beam path.

17. The apparatus of claim 16, wherein the one or more metasurfaces are configured to provide quarter-wave retardation to circularly polarize light transmitted from a light source blade toward an atomic vapor cell blade.

18. The apparatus of claim 1, wherein the cage structure provides mechanical support sufficient to maintain optical alignment of components on the blade modules during the assembly process.

19. The apparatus of claim 1, wherein the cage structure is configured to be compatible with automated pick-and-place assembly equipment.

20. A quantum device system comprising:
a plurality of modular blade assemblies, each blade assembly carrying a distinct quantum device function;
a cage structure that receives and mechanically aligns the blade assemblies in a fixed spatial relationship; and
a circuit substrate electrically connected to the blade assemblies while the blade assemblies are retained within the cage structure.

21. The system of claim 20, wherein the modular blade assemblies include at least a light source blade, an atomic vapor cell blade, and a photodetector blade.

22. The system of claim 20, wherein the cage structure maintains alignment of the blade assemblies during reflow soldering.

23. The system of claim 20, wherein the cage structure contributes structural rigidity sufficient to improve resistance to shock and vibration in the assembled quantum device.

24. The system of claim 20, further comprising one or more optical elements positioned between adjacent blade assemblies within the cage structure, the one or more optical elements being transmissive to visible and near-infrared wavelengths while attenuating thermal radiation transfer between adjacent blade assemblies.

25. The system of claim 24, wherein the one or more optical elements are configured to be slidably receivable into one or more slots of the cage structure.

26. The system of claim 24, wherein the one or more optical elements comprises a metasurface configured to modify at least one property of light transmitted therethrough, including at least one of a polarization state, a beam collimation, an optical density, a beam size, a beam profile, and a beam path.

27. The system of claim 20, wherein the quantum device system is configured as an atomic clock.

28. A method of manufacturing a modular quantum device, comprising:
independently manufacturing and testing a plurality of blade modules, each blade module providing a distinct quantum device function;
inserting the tested blade modules into corresponding slots of a cage structure to establish a predetermined alignment;
positioning a circuit substrate relative to the blade modules; and
electrically connecting the blade modules to the circuit substrate while the cage structure maintains the predetermined alignment.

29. The method of claim 28, wherein electrically connectingcomprises reflow soldering.

30. The method of claim 28, wherein inserting the tested blade modules comprises reading blade identification data from a non-volatile memory on each blade module to verify correct slot placement prior to electrically connecting the blade modules to the circuit substrate.

31. The method of claim 28, wherein inserting the blade modules into the cage structure is performed using automated pick-and-place equipment.

32. The method of claim 28, further comprising reworking the modular quantum device by:
thermally releasing the circuit substrate from one or more blade modules;
removing at least one blade module from the cage structure;
inserting a replacement blade module into the corresponding slot; and
re-joining the circuit substrate to the blade modules.

33. The method of claim 32, wherein thermally releasing comprises desoldering the circuit substrate.

34. The method of claim 32, further comprising:
independently testing the replacement blade module prior to insertion.

35. The method of claim 34, wherein independently testing the blade modules comprises testing each blade module at its target operating temperature prior to integrating with other blade modules.
